(19) United States
(12) Patent Application Publication
(10) Pub. No.: US 2002/0150185 A1
(43) Pub. Date: Oct. 17, 2002

(54) Diversity combiner for reception of digital television signals

(76) Inventors: Joseph Meehan, New York, NY (US); Patrick Kelliher, Belmont, MA (US); Gene Turkenich, Hillsdale, NJ (US); Monisha Gosh, Chappaqua, NY (US)

Correspondence Address: John F. Vodopia, Corporate Patent Counsel, Philips Electronics North America Corporation, 580 White Plains Road, Tarrytown, NY, 10591, US

(21) Appl. No.: 09/820,594

(22) Filed: Mar. 29, 2001

(51) Int. Cl. H04L 1/02; H03H 7/30; H03H 7/40

(52) U.S. Cl. 375/347; 375/229

(57) ABSTRACT

An apparatus and method for improving signal reception in a signal receiver is disclosed. The apparatus comprises at least two first receiver chips, a digital combiner circuit and a single third receiver chip. At least two antennae are used to receive at least two signals, the signals are passed through front end section and equalizer of the first receiver chips, wherein the quality of the signals is evaluated. The signals are combined intelligently in the digital combiner circuit based on the quality of each signal. The combined result is fed into the decoder located in the back-end section of the singe third receiver chip.

### TECHNICAL FIELD OF THE INVENTION

The present invention is directed, in general, to antenna systems and signal receivers and, more specifically, to an apparatus for and method of improving the reception of signals such as digital television signals used in digital terrestrial televisions.

### BACKGROUND OF THE INVENTION

The “digital revolution” for television began in the early 1990's, when the first satellite operators started to broadcast signals in digital format. Since then Digital Television (DTV) systems have started to replace existing terrestrial analog NTSC (National Television System Committee) television systems.

Several simultaneous Standard Definition Television (SDTV) image streams or a single High Definition Television (HDTV) image will typically make up digital television programming broadcasts. SDTV is considered roughly the same quality level as today's analog television broadcasts and HDTV relates to a number of higher definition video standards, which significantly enhance the quality of the picture on a screen and the quality of the sound. Both of these broad television standards are considered to be within ATSC (Advanced Television Standards Committee) standard, a new standard launched in 1994 by the United States for terrestrial broadcasts. In order to drive the consumers to change their old television sets with receivers, and to visually enhance the TV experience, the ATSC standard is HDTV compatible. HDTV standard images allow up to 6 times the resolution of analog television images and up to a full 60 frames per second temporal resolution which is twice the current NTSC resolution. Motion is seen smooth and the picture is clear enough to sit very close to a very large screen. The picture is displayed in a panoramic 16:9 horizontal-to-vertical aspect ratio to be more like movies and add the feeling of realism to TV. An HDTV video signal contains almost four to five times the data of an NTSC image.

Receiving an HDTV signal through an indoor antenna has been a challenge ever since the standard was launched. Current indoor antennae are usually connected to television receivers which consist of a single receiver chip. A typical signal receiver system is illustrated in FIG. 1. These receivers receive a low quality signal which is significantly worse than HDTV intended quality. Often, the noise in the signal makes it difficult for the receivers to even receive the signal due to the standard threshold of visibility of 15 dB SNR (Signal to Noise Ratio). As a result receiving a “noisy” television signal with the signal to noise ratio of lower than 15 dB is impossible. There is, therefore, a need for a receiver which allows a signal to be received with an SNR lower than 15 dB.

Moreover, with one directional antenna, placement of the antenna is critical to obtaining satisfactory reception. With the current receiver systems, channel surfing is almost impossible without rotating the antenna. There is, therefore, a need for a receiver which allows the antenna placement to be much less critical.

According to field tests performed by the NAB/MSTV (National Association of Broadcasters in cooperation with the Association for Maximum Service Television Inc.) consortium, as reported on the official ATSC website (http://www.atsc.org), 30% of receiver failures result from weak field strength. There is, therefore, a need for a receiver which reduces the probability that the receiver lies in a low field strength.

### SUMMARY OF THE INVENTION

It is, therefore, an object of the present invention to provide a system and method for improving the reception of a signal in a receiver connected to at least two antennae located indoors or outdoors.

The present invention, which addresses the needs of the prior art provides an apparatus which includes at least two first receiver chips each associated with an antenna, each chip having a front-end section, equalizer, and a back-end section; a digital combiner circuit for receiving signals from said chips, the digital combiner circuit having at least two first buffer memories, at least two second buffer memories, and a clock synchronizing module, with each buffer memory generating an output signal; a common bus coupled to the first receiver chips and the digital combiner circuit; the clock synchronizing module capable of generating a delay signal and aligning the output signal of each buffer memory based on a common clock; the digital combiner circuit capable of generating a combined output signal; and a single second receiver chip for receiving the combined output signal of the digital combiner circuit, the second receiver chip comprising a front-end section, equalizer and a back-end section.

In another embodiment, a method is provided which includes receiving first and second signals from the first and second antennae in the first receiver chips; processing the signals in a digital combiner circuit that includes first and second buffer memories and a clock synchronizing module, so as to generate a delay signal that synchronizes and combines output signals from the buffer memories to generate a combined output signal; and feeding the combined output signal to a single second receiver chip.

The above, as well as further features of the invention and advantages thereof, will be apparent in the following detailed description of certain advantageous embodiments which is to be read in connection with the accompanying drawings forming a part hereof, and wherein corresponding parts and components are identified by the same reference numerals in the several views of the drawings. The scope of the present invention will be pointed out in the appended claims.

### BRIEF DESCRIPTION OF THE DRAWINGS

Embodiments of the invention are now described by way of example with reference to the following figures in which:

FIG. 1 is a block diagram of a signal receiver apparatus in accordance with prior art;

FIG. 2 is a block diagram of an illustrative embodiment of a signal receiver apparatus in accordance with one embodiment of the present invention;

FIG. 3 is a block diagram illustrating communications among the receivers in the apparatus of FIG. 2 in accordance with one embodiment of the present invention; and

FIG. 4 is flow diagram illustrating maximum ratio combining algorithm utilized in one embodiment of the present invention.

### DETAILED DESCRIPTION OF THE PREFERRED EMBODIMENT(S)

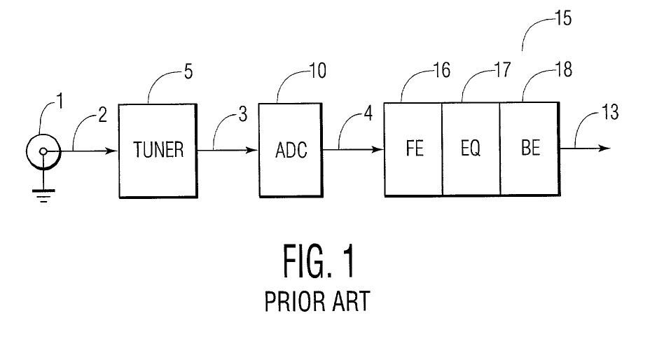

As shown in FIG. 1, a typical signal receiver system comprises an antenna 1 for receiving a television signal coupled to a tuner 5 which receives an intermediate frequency (IF) signal 2 and down-converts the signal to a low IF signal 3. Generally, the standard IF signal is a 44 Mhz signal and the low IF signal is a signal of less than 10 Mhz. The low IF signal 3 is then converted into a digital signal 4 by an analog to digital converter (ADC) 10. A receiver chip 15, comprising a front-end section (FE) 16, equalizer (EQ) 17 and a back-end section (BE) 18, receives the digital signal 4 and processes the signal in all three sections. The receiver chip 15 is preferably an ATSC A/53 compliant chip, which means that it is capable of receiving an 8-VSB signal, an 8 level ({±1, ±3, ±5, ±7}) VSB signal broadcasted in a terrestrial broadcast mode over the same 6 MHz channel currently used by the analog NTSC television system. The number and letters 8-VSB refer to a television signal modulation format in which the television signal has eight vestigial sidebands. A typical standard symbol rate is 10.76 MHz.

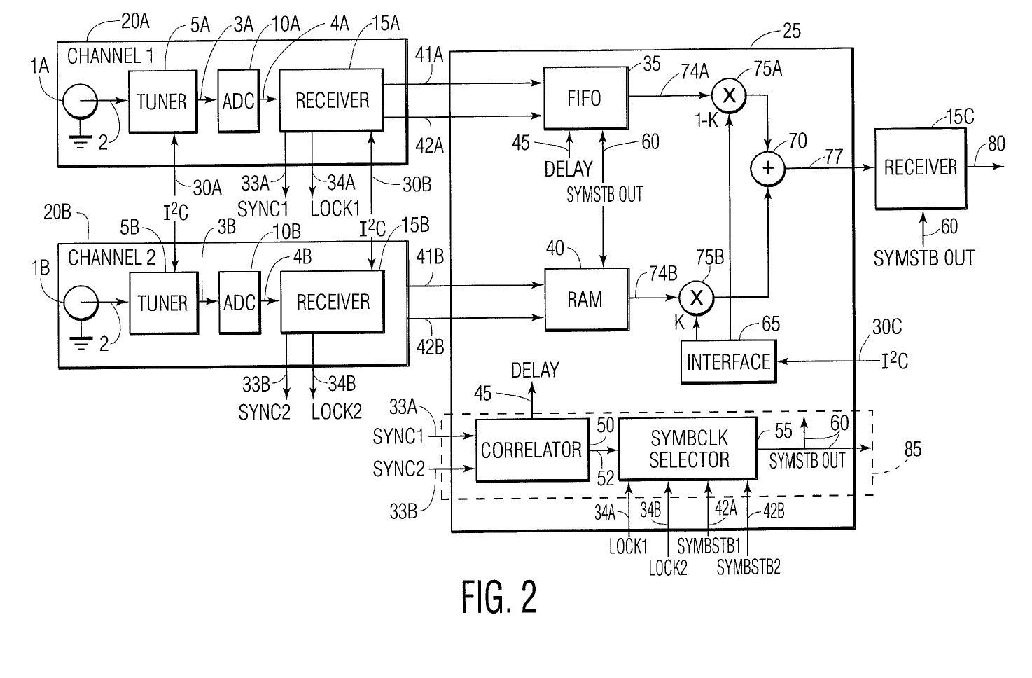

According to a preferred embodiment of the present invention as illustrated in FIG. 2, multiple, and at least two, ATSC A/53 compliant DTV receiver chips 15A, 15B and 15C are combined on one board to act as a diversity combiner receiver that will improve receiver performance for digital terrestrial TV. In particular, antennae 1A and 1B receive two different IF signals 2A-2B, which are passed to tuners 5A-5B. The use of two antennae instead of one provides a higher probability of receiving the signal. An I²C bus 30A is electrically coupled to integrated chip (IC) boards 20A-20B and establishes communication between the tuners 5A-5B. The tuners 5A-5B are then tuned to the same channel through the I²C bus 30A, which is controlled and programmable by a computer (not shown). Alternatively, the bus 30A may be controlled by a television set. The tuners 5A-5B must be receiving the same signal. The computer will typically have standard communications software installed for controlling the I²C bus 30A. The tuners 5A-5B down-convert the IF signals 2A-2B to low IF signals 3A-3B, which are then converted into digital signals 4A-4B by analog to digital converters 10A-10B, respectively.

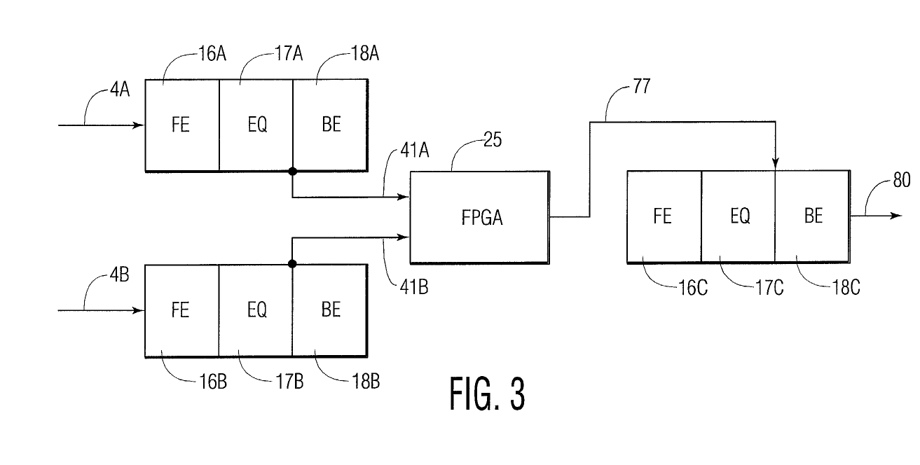

The receiver chips 15A-15B receive the digital signals 4A-4B at the front-end sections 16A-16B and process the signals in the front-end section 16A-16B and the equalizer 17A-17B. As illustrated in FIG. 3, the back-end section 18A-18B is not used. The front-end section of the receiver chip is typically utilized for timing recovery purposes, while the equalizer is utilized as a demodulator for removing interferences and echoes. The back-end section is utilized as a decoder, in particular for forward error correction (FEC) processing.

All of the outputs of the receiver chips 15A-15B are fed into a digital combiner circuit 25. In a preferred embodiment of the invention, the digital combiner circuit 25 is a field programmable gate array (FPGA). Alternatively, the digital combiner circuit 25 may be a digital signal processor (DSP) or software run on a computer. Sync outputs 33A-33B are fed into a correlator 50 of a clock synchronizing module 85. Sync outputs 33A-33B indicate when the segment sync is to arrive. The segment sync is transmitted vertically in a standard ATSC signal. Based on these sync outputs, correlator 50 generates a delay signal 45 which is a time difference between the two signals 4A-4B. For example, the signal on channel 1 might arrive 0.1 microseconds before the signal on channel 2, i.e. antenna 1A receives the signal earlier than the antenna 1B. Thus, the delay 45 is generated. The correlator 50 typically acts as a subtractor, which calculates the time difference between the two sync signals, i.e. the correlator 50 notifies the digital combiner 25 of the offset in time between the two data streams and hence what the delay 45 is on one of streams for the buffer memory 35. The correlator 50 then averages the offset over multiple sync signals. The correlator 50 also generates a synchronization output signal 52, which is fed into the symbol clock selector 55. The synchronization output signal 52 notifies the system where the data stream is within the ATSC structure. Each receiver chip knows independently where its data stream is within the ATSC frame.

The receiver chips 15A-15B also generate lock signals 34A-34B, which represent the existence of the signals 4A-4B or lack thereof, i.e. the lock signals indicate whether the signal has been acquired. The other outputs of the receiver chips 15A-15B are equalizer outputs 41A-41B and symbol strobe outputs 42A-42B, which act as inputs to buffer memories 35 and 40. The lock signals 34A-34B and symbol strobe signals 42A-42B are then fed into a symbol clock selector 55. The symbol strobe signals 42A-42B, preferably, operate at a frequency of 10.76 MHz. As a result, there are two clocks corresponding to each symbol strobe 42A-42B, i.e. each receiver chip is operating at a different clock. However, since the signals are to be combined the result must operate on one clock. Therefore, there is switching that occurs between the two clocks, which might result in some clock glitches. In order to minimize the clock glitches, 12 MHz signals may be used instead of 10.76 MHz. In response to the inputs 34A-34B and 42A-42B, symbol clock selector 55 generates a symbol strobe output 60, which is selected as a common clock of the system illustrated in FIG. 2.

The first memory buffer is preferably a first-in first-out memory (FIFO) 35. This means that the data written into the buffer first, comes out first. The second memory buffer is preferably a random access memory (RAM) 40. The FIFO 35 is preferably implemented with hardware, however, an alternative implementation with software is also possible. The FIFO 35 receives the equalizer output signal 41A and the symbol strobe signal 42A. So the equalizer output signal 41A is written into the FIFO 35 based on the symbol strobe 42A. The two incoming 10.76 MHz symbol streams are aligned such that each symbol is added to the respective symbol from the other stream. It is expected that no more than 1-2 symbols variation (<200 ns) will exist between each path. This means that a relatively short FIFO may be used. For example, for a 2 symbols variation, a 4 symbol in length FIFO may be used. The respective field synchronization outputs can be used to align the symbol streams. The field synchronization outputs are part of the standard ATSC signal. The ATSC standard has data structured in fields—for every 312 segments of data, there is one segment called a field sync to create the complete ATSC field. This field sync can be used to align the data streams. The symbol clock selector 55 selects the symbol strobe 42A or 42B and generates the symbol strobe output signal 60. The delay signal 45 generated by the correlator 50 is also fed into the FIFO 35. Based on this delay signal 45, the FIFO 35 delays the signal 41A so that the buffer output signals 74A-74B are exactly synchronized and arrive at points 75A and 75B at the same time. The FIFO is typically measured in terms of depth, which represents the length of the FIFO. In a preferred embodiment, the length of the FIFO is equal to the delay. For example, the FIFO of 8×16 (8 bits per symbol with a 16 symbol array in length) may be used. The buffer output signals are read out at the same time based on the symbol strobe output 60, which is fed into each buffer 35 and 40 from the symbol clock selector 55.

Besides the mentioned outputs, the receiver chips 15A-15B also generate a signal quality indicator (SQI) output (not shown). An I²C bus 30B which is electrically coupled to receiver chips 15A-15B has an input and an output. The I²C bus 30B reads the SQI output out of the receiver chips 15A-15B. The SQI value is typically generated in software run on the computer (not shown). The standard ATSC signal has a frame sync transmitted horizontally and a segment sync transmitted vertically. The frame sync acts as a training signal; once it arrives the entire signal following it becomes apparent. The anticipated signal is then compared to what has actually arrived and on the basis of the comparison, SNR (signal-to-noise ratio) is generated within each receiver chip. SQI is derived from the SNR.

Maximum Ratio Combining

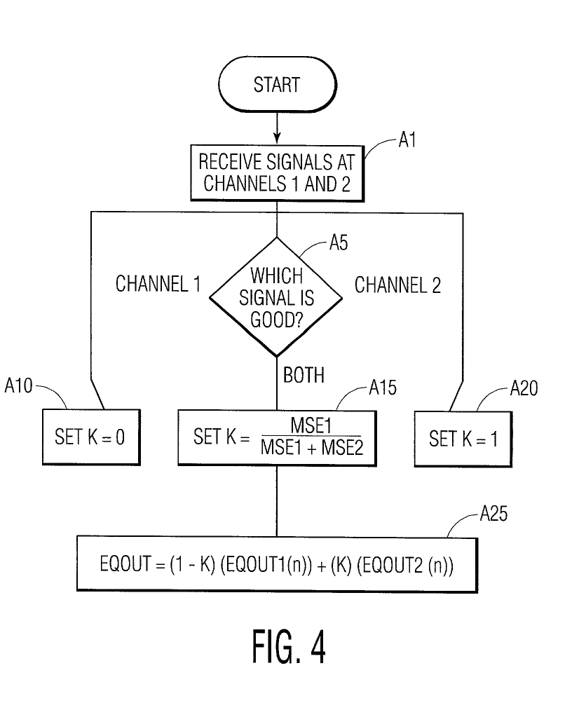

An I²C bus 30C is electrically coupled to the digital combiner circuit 25, and in particular to an interface module 65, which applies weighting factors K and 1−K to the buffer output signals 74A-74B. The weighting factors are determined using a maximum ratio combining algorithm illustrated in FIG. 4.

After receiving the signals at step A1, the quality of each signal is determined within the receiver chips and communicated through the I²C bus. SQI represents the quality of the signal. In a preferred embodiment of the invention, mean squared error (MSE) is used for SQI. Alternatively, other functions of measuring an error in a signal may be used. A known field sync arrives every 24 milliseconds as a part of a standard ATSC signal. The field sync is known beforehand because, based on the symbol strobe signals 42A-42B and the sync clock signals 33A-33B, the exact position in the frame is known. Therefore, since a standard frame is known to be 832 by 313 symbols, the exact time when the next frame will arrive is known. The field sync is compared to what has actually arrived and from this comparison the MSE is calculated. Performing the same procedure for each channel for multiple field syncs and averaging out the MSEs produces an average MSE, which is the SQI. The lower the MSE on a channel, the better the signal quality. The reverse is also true: the higher the MSE, the worse the signal quality is. At step A5 the above described procedure of determining the quality of a signal is executed. If only the signal at channel 1 is good, and the signal at channel 2 is not to be used, the weighting factor K is set to zero at step A10. If only the signal at channel 2 is good, the weighting factor K is set to one at step A20. If the signals are good at both channels, they are combined intelligently by an adder 70 at step A15, wherein K is set to:

K=MSE1/(MSE1+MSE2) (EQ. 1)

The combined output signal 77 (eqout) is calculated at step A25:

Eqout=(1−K)(eqout1(n))+(K)(eqout2(n)), (EQ. 2)

where weighting factor K is between zero and one. The closer K is to zero the more channel 1 signal is dominant. The closer K is to one the more channel 2 signal is dominant. The combined output signal 77 is then fed into a receiver chip 15C. In particular, as illustrated in FIG. 3, the signal 77 is fed only into the back-end section 18C, preferably a forward error correction (FEC) unit, for decoding purposes. The output of the back-end section 18C is a desired digital signal 80. This combined signal 80 is of a significantly better quality than a signal 13 illustrated in FIG. 3. By combining the two signals with different noises, an approximate 3 db gain is achieved. Experimentally, the theoretical threshold of visibility of 14.9 dB SNR is lowered to approximately 12.5 dB with the combination of signals according to the present invention. Moreover, the receiver according to the present invention reduces the probability that the receiver lies in a low field strength area. For example, with n antennae there is n times less chance of being in a field null. Also, the reduced threshold of visibility helps reduce the effect of lower field strength.

In an alternate embodiment, more than two antennae with more than two parallel receiver chains associated with the antennae may be implemented. This will result in a more complex and expensive system than the two antenna system, as those of ordinary skill in the art will appreciate. The digital combiner circuit will become more complex, in particular, and multiple buffer memories will need to be used. For example, for n receiver chains there will need to be (n−1) FIFOs and (n−1) RAMs for n>2. However, only one decoder in a single receiver chip and one clock synchronizing module as in the preferred embodiment will be used.

The apparatus and method of the present invention is not limited to improving only a television signal. Those skilled in the art will readily understand that the principles of the present invention may also be successfully applied to other types of signals.

The terms used herein should be read as terms of description rather than of limitation, as those of skill in the art with this specification before them will be able to make modifications therein without departing from the spirit of the invention. Other embodiments beyond those here discussed are within the spirit and scope of the appended claims.

What is claimed is:

1. An apparatus for improving reception in a receiver having at least two antennae, comprising:
at least two first receiver chips each associated with one of said antennae, each chip comprising a front-end section, equalizer, and a back-end section;
a digital combiner circuit for receiving signals from said chip, said digital combiner circuit comprising at least two first buffer memories, at least two second buffer memories, and a clock synchronizing module, with each buffer memory generating an output signal;
a common bus coupled to said first receiver chips and said digital combiner circuit;
said clock synchronizing module capable of generating a delay signal and aligning said output signal of each buffer memory based on a common clock;
said digital combiner circuit capable of generating a combined output signal; and
a single second receiver chip for receiving said combined output signal of said digital combiner circuit, said second receiver chip comprising a front-end section, equalizer and a back-end section.

2. The apparatus of claim 1 further comprising at least two tuners for receiving IF signals from each antenna and converting said IF signals to low IF signals before forwarding said low IF signals to said first receiver chips.

3. The apparatus of claim 2 further comprising at least two analog to digital converters, each receiving said low IF signal and generating a digital input signal to be forwarded to said first receiver chips.

4. The apparatus of claim 3 wherein each of said first receiver chips generates an equalizer output signal in response to said digital input signal, wherein said digital input signal is processed in said front end section and said equalizer, said equalizer then generating an equalizer output signal.

5. The apparatus of claim 4 wherein each of said first buffer memories and each of said second buffer memories receive said equalizer output signal and generate a synchronized memory buffer output signal, said synchronized memory buffer output signal being weighted based on signal quality indicator value.

6. The apparatus of claim 5, wherein said signal quality indicator value is passed through said common bus, said common bus being controlled by a computer.

7. The apparatus of claim 5, wherein said synchronized memory buffer output is weighted using a maximum ratio combining algorithm.

8. The apparatus of claim 5, wherein said digital combiner circuit further comprises an adder, said adder producing said combined output signal in response to said weighted synchronized memory buffer output signals.

9. The apparatus of claim 1, wherein said second receiver chip receives said combined output signal at said back end section.

10. The apparatus of claim 1, wherein said digital combiner circuit is an FPGA.

11. The apparatus of claim 1, wherein each of said plurality of first buffer memories is a FIFO.

12. The apparatus of claim 1, wherein each of said plurality of second buffer memories is a RAM.

13. An apparatus for improving signal reception in a signal receiver having a first antenna and a second antenna coupled to a first tuner and a second tuner respectively, said first tuner passing a first channel low IF signal into a first analog to digital converter and said second tuner passing a second channel low IF signal into a second analog to digital converter, said analog to digital converters producing digital output signals, said apparatus comprising:
a first receiver chip and a second receiver chip, each coupled to said first and second analog to digital converters respectively, each of said first and second receiver chips comprising a front end section, equalizer and a back end section, wherein said digital output signal from each of said first and second analog to digital converters is passed through said front-end section and said equalizer of each of said first and second receiver chips, said equalizers producing equalizer output signals;
a digital combiner circuit for receiving said equalizer output signals from said first and second receiver chips, said digital combiner circuit comprising:
a first buffer memory for receiving said first equalizer output and a first clock signal from said first receiver chip,
a second buffer memory capable of receiving said second equalizer output and a second clock signal from said second receiver chip,
a clock synchronizing module for generating a delay signal and aligning said first and second output signals from said first and second buffer memories based on a common clock, said delay signal utilized as an input signal into said first buffer memory;
said digital combiner circuit is capable of generating a combined output signal;
a third receiver chip for receiving from said digital combiner circuit, said third receiver chip comprising a front-end section, equalizer and a back-end section, wherein said third receiver chip receives said combined output signal at said back-end section;
a common bus coupled to said first and second tuners, to said first and second receiver chips and to said digital combiner circuit.

14. The apparatus of claim 13, wherein said digital combiner circuit is an FPGA.

15. The apparatus of claim 13, wherein said first buffer memory is a FIFO.

16. The apparatus of claim 13, wherein said second buffer memory is a RAM.

17. The apparatus of claim 13, further comprising an adder for combining weighted outputs of said first and second buffer memories, said adder generating said combined output signal.

18. The apparatus of claim 17, wherein said outputs of said first and second buffer memories are weighted based on a weighting factor, said weighting factor is determined from a signal quality indicator value by utilizing a maximum ratio combining algorithm.

19. A method for improving signal reception in a signal receiver having a first antenna and a second antenna comprising the steps of:
programming a common bus to enable first and second tuners to operate on a same channel;
down-converting first and second IF signals received from said first and second antennae to a first low IF signal and to a second low IF signal respectively;
converting said first and second low IF signals to said first and second digital signals;
modifying said first and second digital signals in a front-end section and an equalizer of a first and second receiver chips to recover timing and to correct distortions in said first and second digital signals;
routing said first and second digital signals to a digital combiner circuit;
delaying said first and second digital signals in a first and second memory buffers based on a delay signal generated by clock synchronizing means;
aligning said first and second digital signals to a common clock;
weighting said first and second digital signals based on a signal quality indicator value;
adding said weighted digital signals;
passing a combined output signal into a back-end section of a third receiver chip;

20. The method of claim 19, wherein said digital signals are weighted using a maximum ratio combining algorithm.

21. A method for improving reception in a receiver having at least first second and antennae, comprising the steps of:
receiving first and second signals from the first and second antennae in first receiver chips;
processing the signals in a digital combiner circuit that includes first and second buffer memories and a clock synchronizing module, in order to generate a delay signal that synchronizes and combines output signals from the buffer memories to generate a combined output signal; and
feeding the combined output signal to a single second receiver chip.
